(19) United States
(12) Patent Application Publication
(10) Pub. No.: US 2009/0142247 A1
(43) Pub. Date: Jun. 4, 2009

(54) Chemical treatment to reduce machining-induced sub-surface damage in semiconductor processing components comprising silicon carbide

(75) Inventors: Jennifer Y. Sun, Sunnyvale, CA (US); Irene A. Chou, San Jose, CA (US); Li Xu, San Jose, CA (US); Kenneth S. Collins, San Jose, CA (US); Thomas Graves, Los Altos, CA (US)

Correspondence Address: SHIRLEY L. CHURCH, ESQ., P.O. BOX 81146, SAN DIEGO, CA, 92138, US

(73) Assignee: Applied Materials, Inc.

(21) Appl. No.: 11/999,083

(22) Filed: Dec. 3, 2007

(51) Int. Cl. H01L 21/302; C01B 31/36

(52) U.S. Cl. 423/345; 438/750; 257/E21.214

(57) ABSTRACT

Method of removing damaged silicon carbide crystalline structure from the surface of a silicon carbide component. The method comprises at least two liquid chemical treatment processes, where one treatment converts silicon carbide to silicon oxide, and another treatment removes silicon oxide. The liquid chemical treatments are typically carried out at a temperature below about 100° C. The time period required to carry out the method is generally less than about 100 hours.

### BACKGROUND

1. Field

Embodiments of the present application relate to the use of chemical solution treatments to remove damaged crystalline structure from the surface of silicon carbide components in general, and in particular from the surface of silicon carbide components of the kind used as semiconductor processing apparatus.

2. Description of Background Art

This section describes background subject matter related to the present invention. There is no intention, either express or implied, that the background art discussed in this section legally constitutes prior art.

Corrosion (including erosion) resistance is a critical property for apparatus components used in semiconductor processing chambers where corrosive environments are present, such as in plasma cleaning and etch processes, and in plasma-enhanced chemical vapor deposition processes. This is especially true where high-energy plasma is present and combined with chemical reactivity to act upon the surface of components present in the environment. It is also an important property when corrosive gases alone are in contact with processing apparatus component surfaces.

Closely related to corrosion resistance is the avoidance of formation of particulates during processing of semiconductor devices. Particulates can contaminate device surfaces during fabrication, reducing the yield of acceptable devices. Although particulates may be created from a number of sources, corrosion of apparatus components in areas which have been machined is a major source for the generation of particulates.

Process chambers, and component apparatus present within semiconductor processing chambers, which are used in the fabrication of electronic devices and micro-electro-mechanical structures (MEMS) are frequently constructed from ceramic materials such as silicon carbide, silicon nitride, boron carbide, boron nitride, aluminum nitride, and aluminum oxide, and combinations thereof.

In some instances, depending on the design and size of the apparatus, it is necessary to use an underlying substrate material in combination with a protective overlying coating. However, this may lead to interfacial problems between the substrate material and the coating material, and may increase the likelihood of corrosion and particulate generation upon exposure of the apparatus to the corrosive environments described above. This is particularly true when the coated substrate must be machined to provide a particular apparatus component. When the size, design, and performance requirements of a component permit, use of a bulk ceramic material to form the entire component is often preferable to the use of a substrate protected by a coating.

Silicon carbide bulk ceramic material has shown considerable promise when used as a bulk material for fabrication of semiconductor processing apparatus. Silicon carbide provides excellent wear and corrosion resistance, outstanding thermal conductivity, thermal shock resistance, low thermal expansion, dimensional stability, excellent stiffness to weight ratio, is particularly non-porous due to a fine grained microstructure, and can be designed to have a broad range of electrical resistivity (where volume resistivity at 20° C. ranges from about 10⁻² to 10⁴ ohm.cm.

The fine grained microstructure typically present in the silicon carbide, which offers the advantageous processing properties described above, is sensitive to machining operations which may be carried out to provide a particular apparatus. Because of the hardness of silicon carbide, there is frequently machining-induced subsurface damage when bulk silicon carbide is ultrasonically drilled, cut to a configuration by diamond grinding, surface grinded, or polished, for example.

This subsurface damage which occurs during machining may not be initially apparent; however, after sufficient exposure to corrosive environments, the machined surfaces begins to corrode and particles are produced from the corroded areas. In the past, to remove the damaged subsurface material, components have been oxidized at high temperature to form a silicon oxide, followed by acid stripping of the oxide, using hydrofluoric acid (HF) solution, for example. However, thermal oxidation treatment requires a minimum of 1 to 3 weeks (depending on the oxidation temperature) followed by the acid solution stripping. The cost of the thermal oxidation equipment is high, due to the requirement of an operating temperature in the range of about 900° C. or higher. In addition, components are available which are manufactured using proprietary (unpublished to the best of the inventors' knowledge) methods of oxidizing the silicon carbide. However, these proprietary methods are said to require weeks, and this results in long production lead times to obtain component parts. There is a need in the semiconductor industry for a method of treating machined silicon carbide surfaces to remove the damaged subsurface materials more rapidly, to reduce costs and manufacturing time delays.

### DESCRIPTION

Embodiments of the invention are useful in the treatment of machined areas present in silicon carbide components of the kind employed as semiconductor or MEMS processing apparatus. The embodiments pertain to a treatment method that removes damaged crystalline structure in the machined areas. The treatment method includes a series of at least two chemical solution treatments, which, in combination, remove machining-induced sub-surface damage from such silicon carbide components. The treated machined areas are essentially free from crystalline damage caused by the machining of the silicon carbide. The treatment method can be applied to components such as showerheads (gas diffusers); process kits, including an insert ring and collar ring, by way of example and not by way of limitation; process chamber liners; slit valve doors; focus rings; suspension rings; susceptors; and pedestals; for example and not by way of limitation. In some embodiments, the chemical solution treatment method reduces particle generation from the areas of the silicon carbide component which have been machined, and improves the lifetime of the component in the corrosive environment in which it is placed. The treatment provides, in a relatively short time (typically about 100 hours or less), a desirable surface which exhibits a round, smooth morphology which produces fewer particulates than experienced by untreated machined silicon carbide surfaces.

Embodiments of the present invention further pertain to a method of surface finishing of a silicon carbide component provides a removal of silicon carbide crystalline material to a depth of about 1 μm to about 5 μm, to ensure that the damage to the crystalline silicon carbide typically caused by machining is removed. This is a requirement for CVD deposited silicon carbide material, which commonly has a grain size of about 2-3 μm. However, the method may be used to remove crystalline material to depths up to about 50 μm, for example, when larger grain sizes are present and it is desired to remove one maximum grain size in depth, or when there is severe machining damage to the component surface in general. This requires a substantially longer time period of treatment, and is not necessary in most instances.

Surface treatment techniques of the exemplary embodiments of the present invention may include three processes or two processes. In a three process method, the surface of the silicon carbide component is first etched, to open the surface for subsequent exposure to an fluid oxidizing agent. This is followed by a second process in which the silicon carbide is oxidized to create silicon oxide. Finally, the silicon oxide is stripped off the silicon carbide surface of the component using an acid solution such as a hydrofluoric acid solution.

The surface opening etch process may be a dry plasma etch process, wherein the plasma etchant is generated from a source gas including oxygen and/or a fluorine-based plasma chemistry; or, is a wet etch process, wherein the etchant is a liquid such as fully concentrated KOH. When the surface-opening etch process is a wet etch process, the temperature at which the etch is performed typically is in the range of about 100° C. or less, and the time period for the etch typically ranges from about 1 hour to about 100 hours.

In a method which employs two processes, the opening etch process may be omitted and only the second and third processes described above are carried out. In the method which employs two processes, in the first treatment process, the silicon carbide surface is exposed to a liquid oxidizing agent which oxidizes the silicon carbide to form silicon oxide, which is more easily removed from the surface than the damaged silicon carbide crystals. The liquid oxidizing agent is selected from the group consisting of KMnO₄; HNO₃; HClO₄; H₂O+H₂O₂+NH₄OH; and H₂O₂+H₂SO₄. The concentration of KMnO₄ may range from about 10 weight % in distilled water to fully concentrated. The concentration of HNO₃ may range from about 10 weight % in distilled water to fully concentrated. The concentration of HClO₄ may range from about 10 weight % in distilled water to fully concentrated. The H₂O+H₂O₂+NH₄OH mixture may be such that the weight ratio of H₂O:H₂O₂:NH₄OH may range from about 1:1:1 to about 1:10:10, where the concentration of the H₂O₂ is about 35 weight % in distilled water, and the concentration of NH₄OH is about 30 weight % in distilled water. The H₂O₂+H₂SO₄ mixture may be such that the weight ratio of H₂O₂:H₂SO₄ may range from about 1:1 to about 1:10, where the concentration of H₂O₂ is about 35 weight % in distilled water, and the concentration of H₂SO₄ is about 93 weight % in distilled water. The treatment temperature typically ranges from about 20° C. to about 200° C. The treatment time for the first, oxidizing process (over this temperature range) typically ranges from about one hour to about one hundred, hours and is more typically about 40 hours or less. The treatment is carried out in an ultrasonic bath. The ultrasonic bath may vary in capacity and in the amount of power applied, depending on the size of the component part, and is typically operated at a frequency ranging from about 25 kHz to about 75 kHz. The ultrasonic bath may be operated at a center frequency of about 40 kHz, with a sweep of frequency ranging upward from 40 kHz to 41 kHz and then downward from 40 kHz to 39 kHz, with the sweep frequency being in the range of 100 Hz, for example and not by way of limitation. The use of a sweep frequency provides additional cavitation and an improved cleaning action.

The two process step method includes a second treatment process in which silicon oxide created in the first treatment process is removed from the surface of the silicon carbide component. Removal of the oxide created in the first process removes the damaged crystalline structure which would have been available to form particulates. The silicon oxide is removed by treating the surface of the component with a second wet etch liquid which includes an acid containing fluorine. A particularly advantageous example is hydrofluoric acid, not by way of limitation. The concentration of HF typically ranges from about 10% by weight in distilled water to about 50% by weight in distilled water. The treatment may be carried out at a wet solution temperature ranging from about 20° C. to about 100° C. The treatment time for the second wet etch process ranges from about 5 minutes to about 10 hours, more typically from about 5 minutes to about 5 hours, depending on the material to be removed from the surface which is being treated. The treatment is carried out in an ultrasonic bath in the manner described with above with reference to the use of an ultrasonic bath.

In certain embodiments, during the first treatment process which is used to produce silicon oxide, the oxide formation slows with time. This slowing of oxide formation is attributed to diffusion-related factors, where the liquid oxidizing agent must penetrate through the already formed silicon oxide layer to reach the silicon carbide beneath the oxide layer. To reduce the total amount of time required to remove damaged silicon carbide crystals to a depth of 2 μm to 5 μm on a component surface, a cyclic process has been developed, in which a first oxidization process is carried out, followed by a second silicon oxide removal process, and this cycle is repeated a number of times until the desired depth of silicon carbide removal from the component surface is achieved.

In conclusion, a method of removing silicon carbide crystalline structure damaged by machining from the surface of a silicon carbide component has been developed. The method includes treating a silicon carbide surface of the component with a liquid oxidizing agent to convert silicon carbide to silicon oxide, followed by treating the silicon oxide with a liquid which removes silicon oxide, where the treatment to convert silicon carbide to silicon oxide and the treatment to remove silicon oxide are each carried out at least one time, or may be repeated in sequence a plurality of times. In some instances, prior to the treatment of the silicon carbide component surface to oxidize the silicon carbide, the surface is opened to make it more receptive to treatment with the liquid oxidizing agent, by treatment of the surface with a plasma or with a liquid etchant which may be a non-oxidizing agent or an oxidizing agent.

The method is used to produce a component which is used as a part of semiconductor or MEMS fabrication apparatus, where at least a portion of the component includes a silicon carbide structure having a machined area which is essentially free from crystalline damage caused by said machining, and free from damage caused by taking the component to a temperature higher than about 500° C. subsequent to shaping of the component. The silicon carbide components which are treated using the method are commonly bulk CVD deposited silicon carbide components. These components are used in the form of a showerhead or gas diffuser, process kit, process chamber liner, slit valve door, focus ring, suspension ring, susceptor, pedestal and baffle, for example and not by way of limitation.

### BRIEF DESCRIPTION OF THE DRAWINGS

So that the manner in which the exemplary embodiments of the present invention are attained and can be understood in detail, with reference to the particular description provided above, and with reference to the detailed description of exemplary embodiments, applicants have provided illustrating drawings. It is to be appreciated that drawings are provided only when necessary to understand the invention and that certain well known processes and apparatus are not illustrated herein in order not to obscure the inventive nature of the subject matter of the disclosure.

FIGS. 1A through 1F show comparison photomicrographs of the surface of CVD silicon carbide bulk test specimens which were exposed to a wet etch by various etchants for 96 hours at 66° C. A smoother, more rounded topography generally indicates that there has been more reaction with the wet etchant solution, as confirmed by the measurement of changes in weight of the test specimens.

FIG. 1A shows a photomicrograph of the silicon carbide surface prior to treatment.

FIG. 1B shows a photomicrograph of the silicon carbide surface after treatment with KOH at a concentration of 43% by weight of the wet etchant, and prior to any processing to remove silicon oxide.

FIG. 1C shows a photomicrograph of the silicon carbide surface after treatment with HClO₄ at a concentration of 70% by weight of the wet etchant in distilled water, and prior to any processing to remove silicon oxide.

FIG. 1D shows a photomicrograph of a silicon carbide surface after treatment with HNO₃ at a concentration of 67% by weight of the wet etchant in distilled water, and prior to any processing to remove silicon oxide.

FIG. 1E shows a photomicrograph of a silicon carbide surface after treatment with a mixture of H₂O₂+H₂SO₄ at a ratio of 1:1, where the concentration of the H₂O₂ was 35% by weight in distilled water and the concentration of H₂SO₄ was 93% by weight in distilled water, and prior to any processing to remove silicon oxide.

FIG. 1F shows a photomicrograph of the silicon carbide surface after treatment with KMnO₄ at a concentration of 80 gr/150 ml of distilled water (35% by weight of KMnO₄ in distilled water), and prior to any processing to remove silicon oxide.

FIGS. 2A through 2D show photomicrographs of the surface of bulk CVD silicon carbide test specimens, where FIG. 2A illustrates no surface treatment, and the other photomicrographs illustrate exposure to a treatment with a KMnO₄ 35% by weight solution for various periods of time, followed by removal of the silicon oxide created by the treatment using an HF stripping solution.

FIG. 2A shows a photomicrograph of the silicon carbide surface prior to any treatment with KMnO₄.

FIG. 2B shows a photomicrograph of the silicon carbide surface after treatment with KMnO₄ for a time period of 12 hours at 68° C. in the ultrasonic bath, followed by removal of the silicon oxide created by the treatment, using an HF stripping solution.

FIG. 2C shows a photomicrograph of the silicon carbide surface after treatment with KMnO₄ for a time period of 24 hours at 68° C. in the ultrasonic bath, followed by removal of the silicon oxide created by the treatment, using an HF stripping solution.

FIG. 2D shows a photomicrograph of the silicon carbide surface after treatment with KMnO₄ for a time period of 36 hours at 68° C. in the ultrasonic bath, followed by removal of the silicon oxide created by the treatment, using an HF stripping solution.

FIG. 3A shows a top view of an exemplary gas distribution plate 300 which has been fabricated from silicon carbide. The thickness of the gas distribution plate 300 typically ranges from about 1 mm to about 6 mm. The gas distribution plate 300 in this particular embodiment includes a total of 374, crescent-shaped through-holes 302 which have been ultrasonically drilled in gas distribution plate 300. The crescent-shaped holes are frequently referred to as “C-slits”.

FIG. 3B shows an enlargement of a section of the gas distribution plate 300, which shows the C-slits in more detail and references an effective width “d” of a slit opening.

### DETAILED DESCRIPTION OF EXEMPLARY EMBODIMENTS

It should be noted that, as used in this specification and the appended claims, the singular forms “a”, “an”, and “the” include plural referents, unless the context clearly dictates otherwise.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of the invention where a drawing would be particularly helpful in understanding the embodiment. Not all embodiments require a drawing for understanding, and therefore the drawings are not to be considered as limiting of the scope of the invention, for the invention may admit to other equally effective embodiments.

A treatment method has been developed for application to silicon carbide components subsequent to machining, to remove machining-induced sub-surface damage from such silicon carbide components. The treatment can be applied to components such as showerheads (gas diffusers); process kits, including but not limited to an insert ring and a collar ring; process chamber liners; and slit valve doors; focus rings; suspension rings; susceptors; and pedestals, for example and not by way of limitation. The chemical solution treatment method reduces particle generation from the areas of the silicon carbide component which have been machined. This significantly reduces particulate formation during the initial operation of the component, and improves the lifetime of the component in the corrosive environment in which it is placed. The treatment provides, in a relatively short time (typically about 36 hours or less), a desirable surface which required several days to weeks to create using previously known methods of treatment.

### EXAMPLES

### Example One

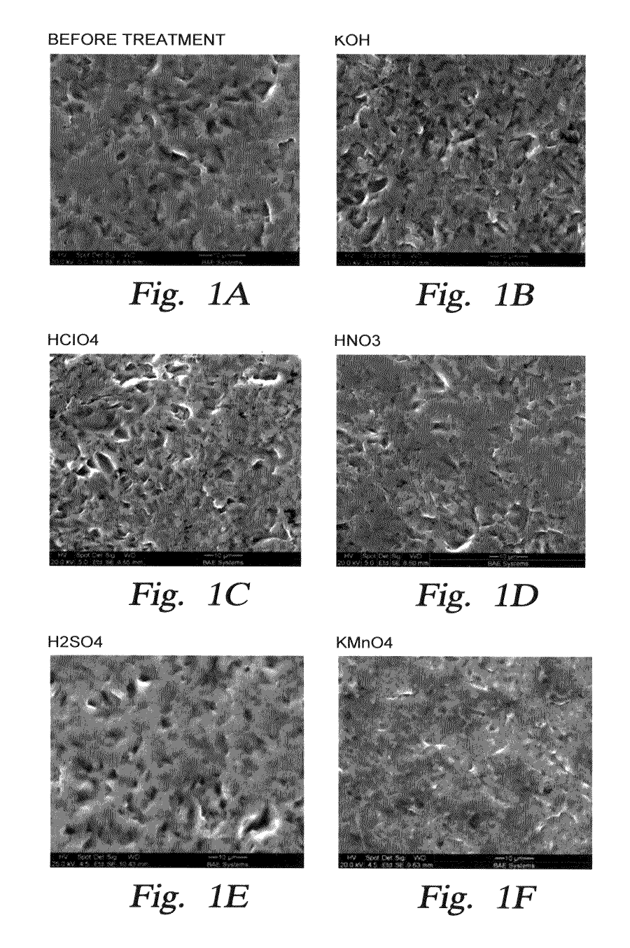

FIGS. 1A through 1F show comparison photomicrographs of the surface of CVD silicon carbide bulk test specimens which were exposed to a wet treatment by various oxidizing agents for 96 hours at 66° C., with the exception of the H₂O₂ and H₂SO₄ oxidizing agent, where the exposure time was 4 hours at 92° C. A smoother, more rounded topography generally indicates that there has been more reaction with the wet oxidizing solution, as confirmed by the measurement of changes in weight of the test specimens. The test specimens measured 10.031 mm in length, 2.062 mm width, and were 1 mm thickness. The weight of an individual test specimen was about 0.65 g, and the total surface area per specimen was 2.839776 cm.

FIG. 1A shows a photomicrograph of the silicon carbide surface after machining, where the surface was diamond grinded using a technique commonly known in the art. One and a half cm on the photomicrograph represents a distance of about 10 μm. The surface has a general roughness which includes numerous thin-edged exposed surfaces.

FIG. 1B shows a photomicrograph of the silicon carbide surface after treatment with KOH at a concentration of 43% by weight of the wet etchant. The test specimen was immersed in an ultrasonic bath which was at a temperature of 65° C. and constantly on at a frequency of about 40 kHz. The test specimen was weighed after 0.5 hr, 1 hr, and 12 hr. The average weight change after 12 hours was a decrease of about 0.00251%. While a specimen treated at 65° C. did appear to have a slightly smoother surface than a specimen treated at 23° C., the change in weight was minimal even at 65° C. after 12 hours of treatment. In view of the need to remove 1 μm to 5 μm of thickness from the surface of the silicon carbide component, the use of a KOH wet etchant does not appear to be as advantageous as other wet etch treatments which were investigated.

FIG. 1C shows a photomicrograph of the silicon carbide surface after treatment with HClO₄ at a concentration of 70% by weight in distilled water. The test specimen was immersed in an ultrasonic bath which was at a temperature of 66° C. at a frequency of about 40 kHz, for a total time period of 96 hours. After 96 hours of wet oxidation treatment with HClO₄, the average weight change was zero. However, when the test specimen was subsequently treated to remove the oxide created by exposure to the HClO₄, a weight change in the test specimen was observed. This indicated that the reaction with the HClO₄ was having an effect, but this effect was masked by counterbalancing reactions, one of which removed silicon carbide, while the other reaction added silicon oxide. The treatment to remove oxide was exposure to a hydrofluoric acid solution at a concentration of 49% by weight in distilled water, at 23° C., for a time period of 30 minutes in the ultrasonic bath which was constantly on at a frequency of 40 kHz. The average weight change after 96 hours of oxidation, followed by removal of the oxidized material was a decrease in weight of 0.00352%.

FIG. 1D shows a photomicrograph of the silicon carbide surface after treatment with HNO₃ at a concentration of 67% by weight in distilled water. The test specimen was immersed in an ultrasonic bath which was at a temperature of 66° C., and at a frequency of about 40 kHz, for a total time period of 96 hours. After 96 hours of oxidation treatment with HNO₃, the average weight change was a decrease of 0.01999%. The test specimen was subsequently treated to remove the oxide created by exposure to the HNO₃. The treatment to remove oxide was exposure to a hydrofluoric acid solution at a concentration of 49 weight % in distilled water, at 23° C., for a time period of 30 minutes in the ultrasonic bath which was at a frequency of 40 kHz. The average weight change after 96 hours of oxidation, followed by removal of the oxidized material was a decrease in weight of 0.02298%.

FIG. 1E shows a photomicrograph of the silicon carbide surface after 7 treatment with a combination of H₂O₂ and H₂SO₄, where the weight ratio of H₂O₂:H₂SO₄ was 1:1, and the concentration of H₂O₂ was 35% by weight in distilled water while the concentration of H₂SO₄ was 93% by weight in distilled water. The test specimen was immersed in a bath which was stirred periodically using a stirring rod. The bat temperature was 92° C. for a total time period of 4 hours. After 4 hours of oxidation treatment with the combination of H₂O₂ and H₂SO₄, the average weight change was a decrease of 0.007516%. The test specimen was subsequently treated to remove the oxide created by the exposure to the H₂O₂ and H₂SO₄ mixture. The treatment to remove oxide was exposure to a hydrofluoric acid solution at a concentration of 49 weight % in distilled water, at 23° C., for a time period of 30 minutes in the ultrasonic bath which was at a frequency of 40 kHz. The average weight change after 4 hours of oxidation, followed by removal of the oxidized material was a decrease in weight of 0.00351%.

FIG. 1F shows a photomicrograph of the silicon carbide surface after treatment with KMnO₄ at a concentration of 80 gr in 150 ml of distilled water (35% by weight). The test specimen was immersed in an ultrasonic bath which was at a temperature of 66° C. and at a frequency of about 40 kHz, for a time period of 96 hours. After 96 hours of oxidation treatment with KMnO₄, the average weight change was a decrease of 0.16104%. The test specimen was subsequently treated to remove the oxide created by exposure to the KMnO₄. The treatment to remove oxide was exposure to a hydrofluoric acid solution at a concentration of 49 weight % in distilled water, at 23° C., for a time period of 96 hours in the ultrasonic bath which was at a frequency of 40 kHz. The average weight change after 96 hours of oxidation, followed by removal of the oxidized material was a decrease in weight of 0.16305%. While these examples made use of a 49 weight % solution of KMnO₄ in distilled water, one skilled in the art should recognize that solutions of other concentrations may be used. Typically, the concentration is higher than about 10% by weight.

In addition to the examples described above, an additional wet oxidation treatment material was evaluated, for which there is no photomicrograph. This oxidant was a solution of H₂O+H₂O₂+NH₄OH. The weight ratio of H₂O:H₂O₂:NH₄OH was 7:6:1, and the concentration of H₂O₂ was 35% by weight in distilled water while the concentration of NH₄OH was 30% by weight in distilled water. The test specimen was immersed in a bath which was periodically stirred using a stirring rod. The treatment bath was at a temperature of 80° C. for a total time period of 4 hours. After 4 hours of oxidation treatment with the combination of H₂O+H₂O₂ and NH₄OH, the average weight change was zero. The test specimen was subsequently treated with a hydrofluoric acid solution at a concentration of 49 weight % in distilled water, at 23° C., for a time period of 30 minutes in the ultrasonic bath, at a frequency of 40 kHz. The average weight change after 4 hours of oxidation, followed by treatment with the hydrofluoric acid solution was 0.000999%.

An oxide layer thickness (achieved after the first wet treatment process) was calculated for each of the test specimens described above, assuming the final weight change measured (after the chemical treatment using a hydrofluoric acid solution) was due to removal of an oxide layer. The test specimen size was 10.031 mm in length and 2.062 mm in width, providing a surface area of 2.839776 cm. The density assumed for the silicon oxide was 2.211 g/cm³. The calculated oxide thicknesses, ranked from maximum to minimum were as follows: KMnO₄=1.725 μm; HNO₃=0.244 μm; H₂O₂ and H₂SO₄=0.037 μm; HClO₄=0.037 μm; KOH=0.037 μm; and H₂O+H₂O₂+NH₄OH=0.0106 μm. Based on the calculated oxide layer thickness, KMnO₄ chemistry was far more effective at removing silicon carbide than the other oxidating agents. However, the combination of H₂O₂ and H₂SO₄ was evaluated on the basis of only a 4 hour treatment. If this 4 hour treatment, followed by removal of the oxide formed, was repeated 24 times, for a total of 96 hours of oxidation treatment, the calculated oxide thickness generated and removed would be about 0.888 μm.

After the above experimentation, it was readily apparent that KMnO₄ was the best performing oxide generating reagent, with the combination of H₂O₂ and H₂SO₄ also looking promising. With this in mind an additional set of experiments was conducted to further investigate the performance of these two wet oxidizing agents.

### Example Two

Test results related to Example One indicated that KMnO₄ and the mixture of H₂O₂+H₂SO₄ were the most promising wet treatment oxidation agents based on data for weight changes and microstructural morphology; and, based on surface profile measurements which indicated flatness of the surface after the silicon oxide layer was stripped off using the hydrofluoric acid solution.

The surface profile measurements were made using surface profilometry measurement length scan (Pmrc %). The Pmrc is the length of bearing surface, i.e., the surface that is in direct contact with the profilometer tip, expressed as a percentage of the evaluation length at a nominal depth below the highest peak. The technique of Pmrc measurement is well known in the art. Pmrc data compliments the SEM examination as an indication of whether the surface has become more smooth. The higher the Pmrc value, the more smooth the length/area of that particular measurement. Typically, a minimum of 11 length/area scans were measured per test specimen to provide an indication of the test specimen surface flatness. The surface flatness was the highest when the wet treatment was carried out using KMnO₄, followed by the H₂O₂+H₂SO₄ mixture, followed by the KOH.

As mentioned above, in view of the overall performance of the H₂O₂+H₂SO₄ mixture and the KMnO₄ treatment materials, additional investigation was carried out using these materials as oxidizing agents.

Test specimens were treated with KMnO₄ for different periods of time, to determine when the progress of the oxidation of the silicon carbide surface was slowed sufficiently by the build up of silicon oxide on the silicon carbide surface, that it would be advisable to remove the silicon oxide from the surface prior to further treatment with the KMnO₄. Six test specimens were made and tested for each time period reported below and the change in weight values shown are the average for the six test specimens in each case.

The treatment of the specimens using the KMnO₄ oxidizing agent was carried out in the same manner as that described with respect to Example One, with the exception that the temperature of the oxidation bath was 68° C. Six sets of test specimens were treated for each of the following time periods: 4 hours, 12 hours, 30 hours, and 60 hours. The average weight change for the specimens after 4 hours of treatment was a decrease of 0.00048%; the weight change after 12 hours of treatment was an increase of 0.00185%; the weight change after 30 hours of treatment was an increase of 0.00158%; and the weight change after 60 hours of treatment was an increase of 0.00310%. The weight changes indicated that the amount of silicon oxide being formed was increasing.

The average weight changes measured for the test specimens after exposure to the hydrofluoric acid solution to remove silicon oxide were as follows. The average weight change for the 4 hour treatment samples was a decrease of 0.00171%; the average weight change for the 12 hour treatment samples was a decrease of 0.00258%; the average weight change for the 30 hour treatment samples was a decrease of 0.00218%; and the average weight change for the 60 hour treatment samples was a decrease of 0.00396%. While there may have been some error in measurement with respect to the hour treatment samples, it is readily apparent that a continual removal of silicon oxide occurred. However, the average rate of silicon oxide removal for the first 4 hours was about 0.0043% per hour, while the average rate of removal for the 12 hour time period and for the 30 hour time period was about 0.0007% per hour. The average rate of removal over the 60 hour treatment was about 0.0005% per hour. Thus, it is clear that the average removal rate slows after about the first four hours. This indicates that it is advantageous to use a cyclic treatment process, where a cycle includes an oxidation process followed by a oxide removal process, and where the cyclic treatment is carried out a number of times depending on the depth of material removal from the component surface which is required.

The oxidation process using KMnO₄ was further investigated by repeating portions of the experiment described above, where the time periods of exposure to the KMnO₄ were 12 hours, 24 hours, 36 hours, and 96 hours, prior to treatment with the hydrofluoric acid solution to remove the oxide. The results were as follows. The average weight change for the six specimens after 12 hours of treatment was a decrease of 0.00184%; the weight change after 24 hours of treatment was a decrease of 0.00577%; the weight change after 36 hours of treatment was a decrease of 0.01015%; and the weight change after 96 hours of treatment was an increase of 0.00717%. The weight changes are masked, as previously discussed, by the competing reactions of silicon oxide formation and silicon carbide removal. However, it is clear that the amount of silicon oxide being formed was increasing, even out to 96 hours.

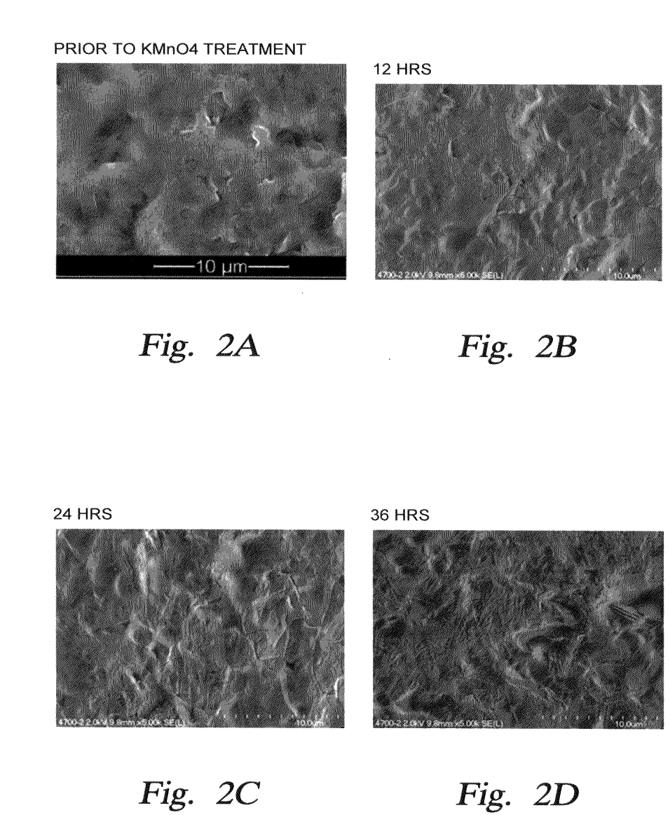

FIGS. 2A through 2D show photomicrographs of the surface of bulk CVD silicon carbide test specimen prior to treatment with the KMnO₄ solution, and after exposure to the wet etch by KMnO₄ for the 12 hour, 24 hour, and 36 hour time periods, respectively, followed by exposure to the hydrofluoric acid stripping procedure previously described herein for removal of silicon oxide from the sample surface. A comparison of the appearances of the oxidized and stripped sample surfaces indicates that the silicon carbide surface is becoming smoother as the oxidation time increases. However, the oxide thickness formed shows non-uniformities. Localized areas on a substrate may vary considerably, by a factor of two or more, in the thickness of the oxide layer formed.

One of skill in the art can optimize the length of time the oxidation reaction should occur for a given component shape and structure, and for a given set of process conditions which are used during the oxidation reaction. The stripping time period and conditions may be optimized to work in combination with the oxidation reaction. To ensure that adequate removal of machining-damaged crystals is achieved, it may be advantageous to use a cyclic approach to removal of damaged silicon carbide crystals from a component surface, where several cycles of oxidation/strip are carried out. This is particularly true as the depth into the component surface which is to be removed increases.

In the evaluation of the KMnO₄ treatment of silicon carbide sample surfaces, the 36 hour time period of treatment, under the conditions described, provided a silicon oxide layer thickness of about removal of silicon carbide crystal to an average depth ranging from about 0.6 μm to about 1.0 μm into the specimen surface. This depth of removal was adequate to provide a smooth surface, based on Pmrc analysis, which should be satisfactory in terms of particulate generation. This judgment is based on the measured smoothness of the silicon carbide surface and our past experience of relating this surface appearance to particulate generation. One of skill in the art may be able to reduce the time period required for treatment by using a cyclic process of the kind described above.

### Example Three

Evaluation of surface oxidation of the bulk CVD silicon carbide test specimen surfaces using the H₂O₂+H₂SO₄ mixture was also further investigated. In particular, the silicon carbide test specimen surfaces were treated with the H₂O₂+H₂SO₄ mixture 3 times, where the soaking time period in the mixture was 4 hours each time, and where the mixture was replaced with fresh H₂O₂+H₂SO₄ after each treatment. The temperature in the soaking bath was 90° C., and there was no ultrasonic vibration induced within the bath. The average change in weight for the six test specimens was a decrease of 0.00053% after the 12 hours of treatment.

A comparison of the 12 hour treatment using the H₂O₂+H₂SO₄ mixture solution with the 12 hour treatment using the KMnO₄ solution indicated that the KMnO₄ solution produced an oxide layer which was about 20% thicker. As a result, the KMnO₄ solution looks more promising at this time, but if the processing conditions are optimized for the H₂O₂+H₂SO₄ mixture, this process may be competitive.

### Example Four

For purposes of example only, we will describe the treatment of a silicon-carbide bonded shower head/gas-diffuser of the kind frequently used during plasma-assisted film deposition processes or during plasma-assisted etch processes. One of skill in the art will recognize that the method which is used to remove damaged silicon carbide crystals in an area which has been machined is applicable to other components of the kind used in semiconductor processing.

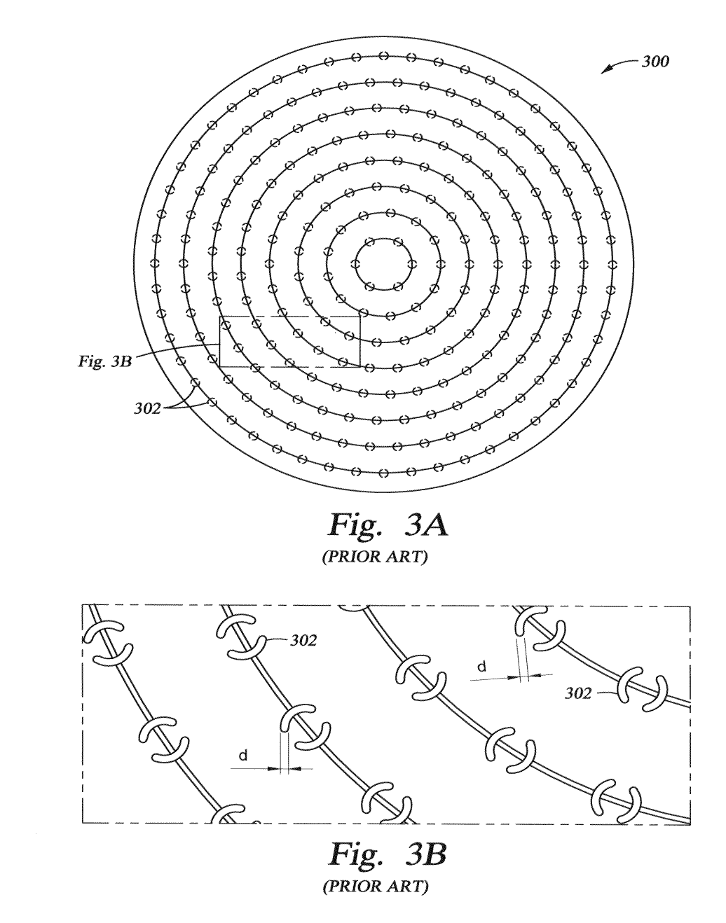

The gas-diffuser component is particularly interesting because it makes use of a large number of openings which must be drilled through a layer of bulk, CVD deposited silicon carbide material. There is considerable damage to the crystalline structure of the silicon carbide in the area surrounding the openings. FIG. 3A shows a top view of a gas-diffuser plate 300, which includes a total of 374 crescent-shaped holes 302 which have been ultrasonically drilled in gas distribution plate 300. The thickness of the gas distribution plate 300 typically ranges from about 1 mm to about 6 mm. The crescent-shaped holes are frequently referred to as “C-slits”.

FIG. 3B shows an enlargement of a section of the gas distribution plate 300, which shows the C-slits in more detail and references an effective width “d” of a slit opening. This effective width “d” is typically in the range of about 650 μm. This width is set to avoid plasma arcing within the C-slits, which occurs if the “d” with is too large. Since the depth of silicon carbide removal estimated to remove damaged crystalline structure is in the range of 2 to 5 μm, the total increase in the width “d” attributable to removal of silicon carbide crystal from both sides of the slit is in the range of 4 to 10 μm and is insignificant with respect to the arcing issue.

Investigation of the formation of the silicon oxide on the silicon carbide surface within the C-slit by Energy Dispersive Spectrometry (EDS) analysis has shown that silicon oxide is chemically present on the wall surface of the C-slit. In the case of the KMnO₄ treatment, some manganese oxide also appeared on the surface. Photomicrographs of the treated C-slit surfaces show that as the oxidation time is extended, the oxide-stripped surface of the C-slit becomes smoother, much in the same manner as described above with respect to the test specimens. The method described herein for removal of damaged silicon carbide crystal from machined areas is particularly important with respect to a gas distribution plate, where machining is used to form the hundreds of openings present in the plate. The lifetime of a gas distribution plate made using the method of the invention described herein would be expected by one skilled in the art to be substantially lengthened, with the number of particulates generated from the gas distribution plate being substantially reduced.

While the foregoing is directed to embodiments of the present invention, other and further embodiments of the invention may be devised in view of the present disclosure, without departing from the basic scope of the invention, and the scope thereof is determined by the claims which follow.

We claim:

1. A method of removing silicon carbide crystalline structure damaged by machining from a surface of a silicon carbide component, comprising:
treating a silicon carbide surface of said component with a liquid oxidizing agent, wherein said treating converts silicon carbide to silicon oxide; and
removing said silicon oxide by treatment with a liquid,
wherein said treating of said silicon carbide surface and said removing of said silicon oxide are each carried out at least one time, or may be repeated in sequence a plurality of times.

2. A method in accordance with claim 1, wherein prior to said treating of said silicon carbide surface with said liquid oxidizing agent, opening said surface of said silicon carbide component to make said surface more receptive to said treating with said liquid oxidizing agent, wherein opening of said surface is accomplished using one of a plasma etching or a liquid etchant, where said etchant is one of a non-oxidizing agent or an oxidizing agent.

3. A method in accordance with claim 1, wherein an amount of silicon carbide is removed from said component surface to a depth of at least 0.05 μm.

4. A method in accordance with claim 3, wherein said depth ranges from about 1 μm to about 50 μm.

5. A method in accordance with claim 4, wherein said depth ranges from about 1 μm to about 5 μm.

6. A method in accordance with claim 1, wherein said treating of said silicon carbide surface with said liquid oxidizing agent is carried out at a temperature ranging from about 20° C. to about 200° C., for a time period ranging from about 1 hour to about 100 hours in an ultrasonic bath.

7. A method in accordance with claim 6, wherein said treating of said silicon carbide surface with said liquid oxidizing agent is carried out for a time period ranging from about 1 hour to about 40 hours.

8. A method in accordance with claim 7, wherein said removing of said silicon oxide is carried out at a temperature ranging from about 20° C. to about 200° C., for a time period ranging from about 5 minutes to about 10 hours in an ultrasonic bath.

9. A method in accordance with claim 8, wherein said treating of said silicon carbide surface with said liquid oxidizing agent and said removing of silicon oxide are repeated in sequence, as a cycle, at least 2 times.

10. A method in accordance with claim 1, wherein said liquid oxidizing agent is selected from the group consisting of KMnO₄, HNO₃, HClO₄, H₂O+H₂O₂+NH₄OH, H₂O₂+H₂SO₄, and combinations thereof.

11. A method in accordance with claim 7, wherein said liquid oxidizing agent is selected from the group consisting of KMnO₄, HNO₃, HClO₄, H₂O+H₂O₂+NH₄OH, H₂O₂+H₂SO₄, and combinations thereof.

12. A method in accordance with claim 9, wherein said liquid oxidizing agent is selected from the group consisting of KMnO₄, HNO₃, HClO₄, H₂O+H₂O₂+NH₄OH, H₂O₂+H₂SO₄, and combinations thereof.

13. A method in accordance with claim 10, said oxidizing agent is KMnO₄.

14. A method in accordance with claim 13, wherein said KMnO₄ concentration ranges from about 10 weight % KMnO₄ in distilled water to fully concentrated in distilled water.

15. A method in accordance with claim 13, wherein a concentration of KMnO₄ ranges from about 10 weight % KMnO₄ in distilled water to about 35% weight % in distilled water.

16. A method in accordance with claim 10, wherein said oxidizing agent is H₂O₂+H₂SO₄.

17. A method in accordance with claim 16, wherein a concentration of H₂O₂+H₂SO₄ is such that the weight ratio of H₂O₂:H₂SO₄ ranges from about 1:1 to about 1:10, where the concentration of H₂O₂ is about 35 weight % in distilled water, and the concentration of H₂SO₄ is about 93 weight % in distilled water.

18. A semiconductor fabrication component comprising: a silicon carbide structure having a machined area, said machined area being essentially free from crystalline damage caused by said machining.

19. A semiconductor fabrication component in accordance with claim 18, wherein said component is free from damage caused by taking the component to a temperature higher than about 500° C. subsequent to shaping of the component.

20. A semiconductor fabrication component in accordance with claim 18, wherein said silicon carbide is bulk CVD-deposited silicon carbide.

21. A semiconductor fabrication component in accordance with claim 19, wherein said silicon carbide is bulk CVD-deposited silicon carbide.

22. A component in accordance with claim 18, wherein said component is selected from the group consisting of a showerhead or gas diffuser, process kit, process chamber liner, slit valve door, focus ring, suspension ring, susceptor, pedestal and baffle.

23. A component in accordance with claim 19, wherein said component is selected from the group consisting of a showerhead or gas diffuser, process kit, process chamber liner, slit valve door, focus ring, suspension ring, susceptor, pedestal and baffle.
